(19) United States
(12) Patent Application Publication
(10) Pub. No.: US 2024/0162211 A1
(43) Pub. Date: May 16, 2024

(54) METHOD FOR PRODUCING AN OPTOELECTRONIC SEMICONDUCTOR CHIP AND OPTOELECTRONIC SEMICONDUCTOR CHIP

(71) Applicant: ams-OSRAM International GmbH, Regensburg (DE)

(72) Inventors: Christian LAUER, Pettendorf (DE); Jens EBBECKE, Rohr In Niederbayern (DE)

(73) Assignee: ams-OSRAM International GmbH, Regensburg (DE)

(21) Appl. No.: 18/550,337

(22) PCT Filed: Feb. 9, 2022
(86) PCT No.: PCT/EP2022/053108

§ 371 Date: Sep. 13, 2023

(30) Foreign Application Priority Data
Mar. 15, 2021 (DE) 102021106238.1

(51) Int. Cl. H01L 25/16; H01L 33/00; H01L 33/02; H01L 33/06; H01L 33/20

(52) U.S. Cl. CPC H01L 25/167; H01L 33/005; H01L 33/025; H01L 33/20; H01L 33/06

(57) ABSTRACT

The invention relates to a method for producing an optoelectronic semiconductor chip, component, including the following steps: —providing an epitaxial semiconductor layer sequence with an active zone, which is configured to generate electromagnetic radiation during operation, —structuring the epitaxial semiconductor layer sequence so that at least one lateral surface is produced in the epitaxial semiconductor layer sequence, —introducing aluminum atoms at the lateral surface into the epitaxial semiconductor layer sequence, so that a band gap of the active zone at the lateral surface is increased. The invention also relates to an optoelectronic semiconductor chip.

### CROSS-REFERENCE TO RELATED APPLICATIONS

The present application is a national stage entry from International Application No. PCT/EP2022/053108, filed on Feb. 9, 2022, published as International Publication No. WO 2022/194453 A1 on Sep. 22, 2022, and claims priority to German Patent Application No. 10 2021 106 238.1, filed Mar. 15, 2021, the disclosures of all of which are hereby incorporated by reference in their entireties.

### BACKGROUND OF THE INVENTION

A method of manufacturing an optoelectronic semiconductor chip and an optoelectronic semiconductor chip are provided.

A method of manufacturing an improved semiconductor optoelectronic chip and an improved semiconductor optoelectronic chip are to be provided.

In particular, an edge-emitting laser diode chip is to be provided in which the risk of damage to a facet during operation due to COD (short for catastrophic optical damage) is reduced. Furthermore, in particular a light emitting diode chip with comparatively small edge length and high efficiency is to be provided. Furthermore, in particular a method for manufacturing such an edge emitting laser diode chip and such a light emitting diode chip is to be provided.

These objects are solved by a method with the steps of claim 1 and by an optoelectronic semiconductor chip with the features of claim 15.

Advantageous embodiments and further developments of the method and the optoelectronic semiconductor chip are the subject of the respective dependent claims.

### SUMMARY OF THE INVENTION

According to one embodiment of the method for manufacturing an optoelectronic semiconductor chip, a semiconductor layer sequence with an active zone is provided which is suitable for generating electromagnetic radiation during operation. Particularly preferably, the epitaxial semiconductor layer sequence is part of a semiconductor wafer.

Particularly preferably, a large number of semiconductor chips are produced in the present method. Preferably, the semiconductor chips are designed in the same way. Features and embodiments described here only in connection with one semiconductor chip can also be implemented in some or all semiconductor chips.

For example, the epitaxial semiconductor layer sequence and in particular the active zone is based on or formed of a nitride compound semiconductor material. Nitride compound semiconductor materials are compound semiconductor materials containing nitrogen, such as the materials from the system InₓAl_{y}Ga_{1-y}N with 0≤x≤1, 0≤y≤1 and x+y≤1

Furthermore, it is also possible that the epitaxial semiconductor layer sequence and in particular the active zone is based on or formed from a phosphide compound semiconductor material. Phosphide compound semiconductor materials are compound semiconductor materials containing phosphorus, such as the materials from the system InₓAl_{y}Ga_{1-x-y}P with 0≤x≤1, 0≤y≤1 und x+y≤1.

According to a further embodiment of the method, the epitaxial semiconductor layer sequence and in particular the active zone is based on or formed of an arsenide compound semiconductor material. Arsenide compound semiconductor materials are compound semiconductor materials containing arsenic, such as the materials from the system InₓAl_{y}Ga_{1-y}As with 0≤x≤1, 0≤y≤1 und x+y≤1.

For example, the epitaxial semiconductor layer sequence is based on InGaN, InGaP or InGaAs or consists of one of these materials.

According to a further embodiment of the method, the epitaxial semiconductor layer sequence is structured such that at least one side surface is formed in the epitaxial semiconductor layer sequence. For example, the epitaxial semiconductor layer sequence is structured such that a plurality of side surfaces are formed in the epitaxial semiconductor layer sequence. In particular, when the epitaxial semiconductor layer sequence is part of a semiconductor wafer, a plurality of side surfaces is generated in the epitaxial semiconductor layer sequence during structuring. Structuring of the epitaxial semiconductor layer sequence is carried out, for example, by means of etching, such as wet-chemical or dry-chemical etching. In particular, for the generation of side surfaces of a laser diode chip, the side surfaces can also be generated by breaking.

For better understanding, features and embodiments of the side surface are generally described in the singular. Features and embodiments described below only in connection with one side surface can also be formed on all or some side surfaces of the epitaxial semiconductor layer sequence.

If an edge-emitting laser diode chip is generated in the method, the side surface is preferably the facet of the edge-emitting laser diode chip over which electromagnetic laser radiation is emitted during operation of the laser diode chip.

According to a further embodiment of the method, aluminum atoms and/or aluminum ions are introduced into the epitaxial semiconductor layer sequence at the side surface so that a band gap of the active zone at the side surface is increased. Preferably, a direction along which the aluminum atoms and/or the aluminum ions are introduced into the epitaxial semiconductor layer sequence runs along a main surface of the epitaxial semiconductor layer sequence.

In particular, the aluminum atoms and/or the aluminum ions are introduced into the active zone of the epitaxial semiconductor layer sequence from the side surface of the epitaxial semiconductor layer sequence so that the band gap of the active zone is increased.

For example, the band gap is increased by a value corresponding to a decrease in the wavelength of the electromagnetic radiation generated by the active zone due to the increase in the band gap between 20 nanometers and 50 nanometers, inclusive.

Preferably, a content of introduced aluminum atoms and/or introduced aluminum ions in the material of the epitaxial semiconductor layer sequence at the side surface continuously decreases along the direction of the main surface of the epitaxial semiconductor layer sequence, for example exponentially.

In particular, in the present method, it is intended to introduce the aluminum atoms and/or the aluminum ions into the epitaxial semiconductor layer sequence via the side surface and not via a main surface of the epitaxial semiconductor layer sequence that runs parallel to the active zone. Thus, the introduction of the aluminum atoms and/or the aluminum ions is significantly more effective than in the case of an introduction via the main surface of the epitaxial semiconductor layer sequence, since not so much semiconductor material of the epitaxial semiconductor layer sequence has to be penetrated by the aluminum atoms and/or the aluminum ions. In addition, the method can be carried out at comparatively low temperatures and the aluminum atoms and/or the aluminum ions can be introduced into the epitaxial semiconductor layer sequence in a more targeted manner.

According to a particularly preferred embodiment of the method, the method of manufacturing an optoelectronic semiconductor chip comprises the following steps:
providing an epitaxial semiconductor layer sequence having an active zone configured to generate electromagnetic radiation in operation,
structuring the epitaxial semiconductor layer sequence so that at least one side surface is formed in the epitaxial semiconductor layer sequence,
introducing of aluminum atoms and/or aluminum ions at the side surface into the epitaxial semiconductor layer sequence so that a band gap of the active zone at the side surface is increased.

Preferably, the steps of the method are performed in the order indicated.

According to a further embodiment of the method, the following steps are performed during the introduction of the aluminum atoms and/or the aluminum ions at the side surface into the epitaxial semiconductor layer sequence:
depositing an aluminum-containing layer on the side surface of the epitaxial semiconductor layer sequence, and
annealing of the side surface with the aluminum-containing layer.

After annealing, the side surface can be free of the aluminum-containing layer. Furthermore, it is possible that material of the aluminum-containing layer is still present on the side surface.

Annealing is, particularly, exposure to a temperature, such as by raising the temperature in a reaction volume in which the epitaxial semiconductor layer sequence is provided. For example, the temperature during annealing is between 400° C. and 1200° C., inclusive.

Here, the deposition of the aluminum-containing layer and the annealing of the aluminum-containing layer are particularly preferably carried out in the same, usually evacuated, reaction volume without removing the epitaxial semiconductor layer sequence from the reaction volume between the deposition of the aluminum-containing layer and the annealing of the side surface with the aluminum-containing layer. This simplifies the method and protects the aluminum-containing layer from oxidation.

Furthermore, it is also possible to heat the aluminum-containing layer with irradiation by an external laser, at least in places, so that the aluminum atoms and/or the aluminum ions migrate into the semiconductor material of the epitaxial semiconductor layer sequence in the regions that are heated with the external laser. In particular, during the fabrication of a laser diode chip, for example, only the later facet is heated with the external laser. This has the advantage that the entire epitaxial semiconductor layer sequence is not exposed to temperature, but only the regions in which the aluminum content is to be increased.

The aluminum-containing layer particularly preferably covers the active zone and can also be applied over the entire surface of the side surface of the epitaxial semiconductor layer sequence.

According to a further embodiment of the method, the aluminum-containing layer is deposited on the side surface of the epitaxial semiconductor layer sequence using one of the following methods: evaporation, sputtering, PVD (short for “physical vapor deposition”), ALD (short for “atomic layer deposition”), MBE (short for “molecular beam epitaxy”) or MOVPE (short for “metal organic vapor phase epitaxy”).

According to a further embodiment of the method, a thickness of the aluminum-containing layer has a value between 1 nanometer and 5 nanometers, inclusive. In particular, a lower limit of the thickness of the aluminum-containing layer is the thickness of a monolayer of aluminum.

By depositing a very thin aluminum-containing layer on the side surface of the epitaxial semiconductor layer sequence and a subsequent annealing step, it is possible to introduce the aluminum atoms and/or the aluminum ions into the epitaxial semiconductor layer sequence in a simple manner. The annealing is performed to arrange the aluminum atoms and/or the aluminum ions on the corresponding lattice sites of a crystal structure of the epitaxial semiconductor layer sequence.

According to a further embodiment of the method, the aluminum atoms and/or the aluminum ions are introduced into the epitaxial semiconductor layer sequence with ion implantation or with a focused ion beam (FIB). The focused ion beam, particularly preferably, has aluminum ions or consists of aluminum ions. In this embodiment of the method, it is advantageously possible to dispense with the deposition of an aluminum-containing layer. In other words, the introduction of the aluminum atoms and/or the aluminum ions is carried out directly at the exposed side surface of the epitaxial semiconductor layer sequence.

In this embodiment of the method, the epitaxial semiconductor layer sequence is preferably also annealed after the introduction of the aluminum atoms and/or the aluminum ions. During annealing, the aluminum atoms and/or the aluminum ions diffuse onto the corresponding lattice sites of a crystal structure of the epitaxial semiconductor layer sequence. Particularly preferably, the ion implantation or the focused ion beam is carried out in an evacuated reaction volume in which the annealing also takes place, without the epitaxial semiconductor layer sequence being removed from the reaction volume in between.

According to a further embodiment of the method, the side surface in the epitaxial semiconductor layer sequence is formed with a focused ion beam. The focused ion beam here particularly preferably has aluminum ions or consists of aluminum ions. In this embodiment, the use of a focused ion beam which has aluminum ions or consists of aluminum ions simultaneously introduces aluminum atoms and/or aluminum ions at the side surface into the epitaxial semiconductor layer sequence during the generation of the side surface in the epitaxial semiconductor layer sequence.

Particularly preferably, the side surface thus formed is again annealed to arrange the aluminum atoms and/or the aluminum ions on the corresponding lattice sites of the crystal structure.

In addition or alternatively to an annealing step, it is also possible to perform a burn-in step. In a burn-in step, the epitaxial semiconductor layer sequence is at least temporarily electrically contacted and the active zone is operated so that electromagnetic radiation is generated and emitted through the side surface. By emitting the electromagnetic radiation through the side surface, the side surface is heated so that the aluminum atoms and/or the aluminum ions migrate to the corresponding lattice sites of the crystal structure of the epitaxial semiconductor layer sequence.

Even in this way, the entire epitaxial semiconductor layer sequence is not exposed to temperature, but only the regions in which the aluminum content is to be increased.

According to a further embodiment of the method, a dielectric encapsulation layer is applied to the aluminum-containing layer. Particularly preferably, the dielectric encapsulation layer is applied to the aluminum-containing layer in direct contact. A thickness of the dielectric encapsulation layer is, for example, between 5 nanometers and 200 nanometers, inclusive.

In particular, the dielectric encapsulation layer is provided and configured to protect the aluminum-containing layer, for example when the epitaxial semiconductor layer sequence is removed from a reaction volume after the deposition of the aluminum-containing layer, such as before an annealing or a burn-in step. The dielectric encapsulation layer can also advantageously protect the aluminum-containing layer during further, subsequent method steps.

Furthermore, it is also possible that the dielectric encapsulation layer is applied in direct contact to the epitaxial semiconductor layer sequence. In this case, the dielectric encapsulation layer can promote the formation of vacancies in the material of the epitaxial semiconductor layer sequence, so that aluminum atoms and/or aluminum ions can penetrate more easily into the material of the epitaxial semiconductor layer sequence. Preferably, in this embodiment, the dielectric encapsulation layer has SiO₂ or SiN or consists of one of these materials. Furthermore, in this embodiment, the aluminum atoms and/or the aluminum ions are preferably introduced into the epitaxial semiconductor layer sequence with annealing.

According to a further embodiment, the dielectric encapsulation layer comprises or consists of, for example, one of the following materials: SiN, SiO₂, TaO, TiO₂, AlN, AlO, HfO.

According to a further embodiment of the method, a material of the aluminum-containing layer remaining on the side surfaces is removed from the side surface after the aluminum atoms and/or the aluminum ions have been introduced into the epitaxial semiconductor layer sequence, preferably completely. For example, the removal takes place wet-chemically. In particular, this method step preferably takes place after an annealing or a burn-in step.

According to a further embodiment of the method, the material of the aluminum-containing layer remaining on the side surface is converted into a dielectric after the aluminum atoms and/or the aluminum ions have been introduced into the epitaxial semiconductor layer sequence, preferably completely. For example, the conversion takes place by oxidation or by nitriding. Thus, a short circuit of the active zone can be avoided with advantage.

Finally, it is also possible that material of the aluminum-containing layer remaining on the side surface after the aluminum atoms and/or the aluminum ions have been introduced into the epitaxial semiconductor layer sequence is absorbed by subsequently applied layers.

According to a further embodiment of the method, a spacer layer is arranged between the aluminum-containing layer and the side surface. Preferably, the spacer layer is applied in direct contact to the epitaxial semiconductor layer sequence. Particularly preferably, the spacer layer is impermeable to O₂ or H₂O. Thus, the spacer layer protects the underlying material from oxidation. Further, the spacer layer is particularly formed of a material that is permeable to the aluminum atoms and/or the aluminum ions from the aluminum-containing layer. For example, the spacer layer has or consists of a dielectric. Preferably, the spacer layer has ZnSe or consists of this material.

For example, a thickness of the spacer layer is between 1 nanometer and 50 nanometers, inclusive, or between 5 nanometers and 10 nanometers, inclusive.

If an edge-emitting laser diode chip is produced in the method, the spacer layer also protects the facet in the event of subsequent etching.

According to a further embodiment of the method, a mirror layer is applied on or over the aluminum-containing layer. In particular, the mirror layer is designed and arranged to specularly reflect electromagnetic radiation generated in the active zone. For example, the mirror layer is deposited over the facet as part of a resonator if an edge-emitting laser diode chip is generated in the method. For example, the mirror layer has ZnSe or is made of ZnSe. The mirror layer may further be formed of a plurality of individual layers, which may also have different materials. For example, a thickness of the mirror layer is between 50 nanometers and 5 micrometers, inclusive, or between 250 nanometers and 5 micrometers, inclusive, or between 100 nanometers and 1 micrometer, inclusive.

For example, the method produces an edge-emitting laser diode chip. Here, the side surface is a facet of the edge-emitting laser diode chip.

If an edge-emitting laser diode chip is produced, the introduction of the aluminum atoms and/or the aluminum ions into the epitaxial semiconductor layer sequence can, in particular, comprise the following steps:
applying an aluminum-containing layer, and
operating the edge-emitting laser diode chip so that aluminum atoms and/or aluminum ions from the aluminum-containing layer diffuse into the epitaxial semiconductor layer sequence (burn-in step). In the fabrication of an edge-emitting laser diode chip, the burn-in step can also be self-aligned on the active near-field region. Furthermore, in the fabrication of a laser diode chip, it is possible that the burn-in step is performed prior to the deposition of a mirror layer, since it increases a reflectivity of the side surface and the burn-in step is thus more effective.

According to a further embodiment of the method, the mirror layer is deposited over the aluminum-containing layer. In addition, the spacer layer is arranged between the aluminum-containing layer and the mirror layer.

The spacer layer serves to protect the facet, especially in the case of the finished edge-emitting laser diode chip. The mirror layer also preferably encapsulates the facet. For example, the mirror layer has ZnSe or consists of ZnSe.

According to a further embodiment of the method, a light-emitting diode chip is manufactured, wherein the side surface of the epitaxial semiconductor layer sequence forms a side surface of the light-emitting diode chip. Particularly preferably, the light-emitting diode chip has a comparatively small edge length, for example between 2 micrometers and 100 micrometers, inclusive and preferably between 5 micrometers and 20 micrometers, inclusive. By introducing the aluminum atoms and/or the aluminum ions into the epitaxial semiconductor layer sequence, the band gap in the edge region adjacent to the side surface can advantageously be increased in the case of a light-emitting diode chip with a comparatively small edge length, so that reduced radiation generation is decreased and the efficiency of the light-emitting diode chip is increased.

The method described herein is particularly configured for manufacturing an optoelectronic semiconductor chip, for example an edge-emitting laser diode chip or a light-emitting diode chip. All embodiments and features disclosed herein in connection with the method can also be embodied in the optoelectronic semiconductor chip and vice versa.

According to one embodiment, the optoelectronic semiconductor chip comprises an epitaxial semiconductor layer stack having an active zone configured to generate electromagnetic radiation in operation. For example, the epitaxial semiconductor layer stack is formed from the epitaxial semiconductor layer sequence by forming the side surfaces in the epitaxial semiconductor layer sequence.

Furthermore, the optoelectronic semiconductor chip has a side surface. The side surface of the optoelectronic semiconductor chip is in particular the side surface that is generated in the epitaxial semiconductor layer sequence during the method.

According to a further embodiment of the optoelectronic semiconductor chip, an aluminum content of the epitaxial semiconductor layer stack is increased at the side surface so that a band gap of the active zone is increased at the side surface. In particular, the aluminum content decreases starting from the side surface in the direction along a main surface of the epitaxial semiconductor layer stack, especially preferably continuously.

According to a further embodiment of the optoelectronic semiconductor chip, the aluminum content in the epitaxial semiconductor layer stack and in particular in the active zone decreases continuously starting from the side surface. For example, the aluminum content decreases exponentially starting from the side surface.

### BRIEF DESCRIPTION OF THE DRAWING

Further advantageous embodiments and developments of the method and the optoelectronic semiconductor chip result from the exemplary embodiment described below in connection with the figures.

FIGS. 1 to 6 show schematic sectional views of stages of a method according to an exemplary embodiment.

FIG. 7 shows a schematic perspective view of a stage of a method according to a further exemplary embodiment.

FIG. 8 shows a schematic perspective view of a stage of a method according to a further exemplary embodiment.

FIG. 9 shows a schematic view of a method step according to a further exemplary embodiment.

FIGS. 10 to 12 show partial schematic sectional views of an optoelectronic semiconductor chip according to various exemplary embodiments.

### DETAILED DESCRIPTION

Elements that are identical, similar or have the same effect are given the same reference signs in the figures. The figures and the proportions of the elements shown in the figures are not to be regarded as to scale. Rather, individual elements, in particular layer thicknesses, may be shown exaggeratedly large for better representability and/or understanding.

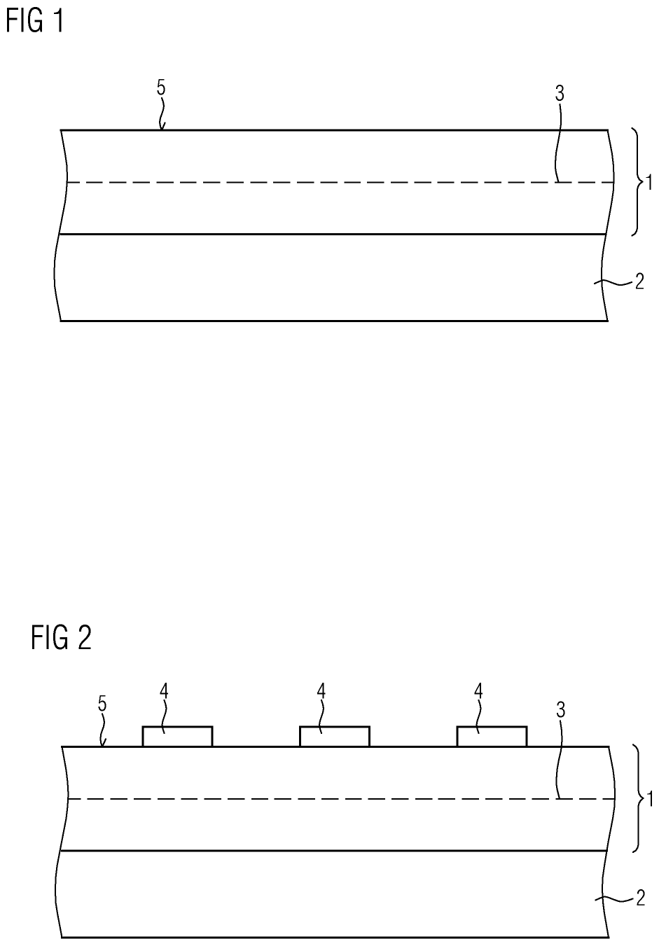

In the method according to the exemplary embodiment of FIGS. 1 to 6, an epitaxial semiconductor layer sequence 1 is provided in a first step (FIG. 1). The epitaxial semiconductor layer sequence 1 is arranged on a substrate 2. For example, the epitaxial semiconductor layer sequence 1 is epitaxially grown on the substrate 2. The epitaxial semiconductor layer sequence 1 further comprises an active zone 3 configured to generate electromagnetic radiation during operation.

In a next step, a structured photoresist layer 4 is applied to a main surface 5 of the epitaxial semiconductor layer sequence 1. The main surface 5 of the epitaxial semiconductor layer sequence 1 runs parallel to the active zone 3 (FIG. 2).

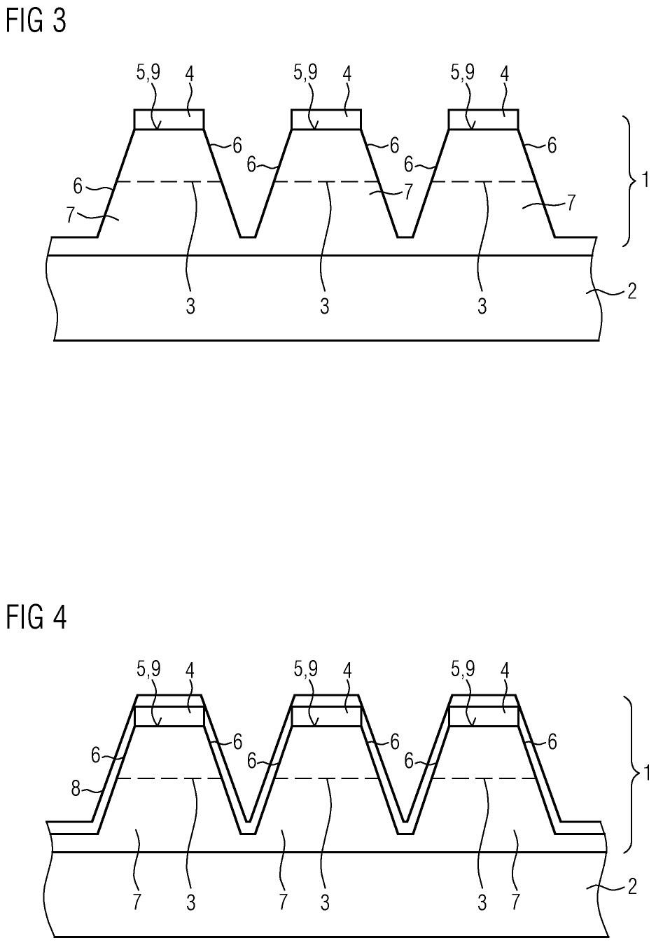

In a next step, the epitaxial semiconductor layer sequence 1 is etched so that the first main surface 5 is structured and side surfaces 6 are formed in the epitaxial semiconductor layer sequence 1. The side surfaces 6 delimit epitaxial semiconductor layer stacks 7. Each epitaxial semiconductor layer stack has an active zone 3 (FIG. 3).

In a next step, an aluminum-containing layer 8 is deposited over the entire surface of the epitaxial semiconductor layer sequence 1. The aluminum-containing layer 8 is deposited on the structured main surface 5 of the epitaxial semiconductor layer sequence 1 using, for example, ALD, MBE or one of the methods already mentioned in the general part. In particular, the aluminum-containing layer 8 covers the side surfaces 6 of the epitaxial semiconductor layer sequence 1 and in particular the active zone 3 (see FIG. 4).

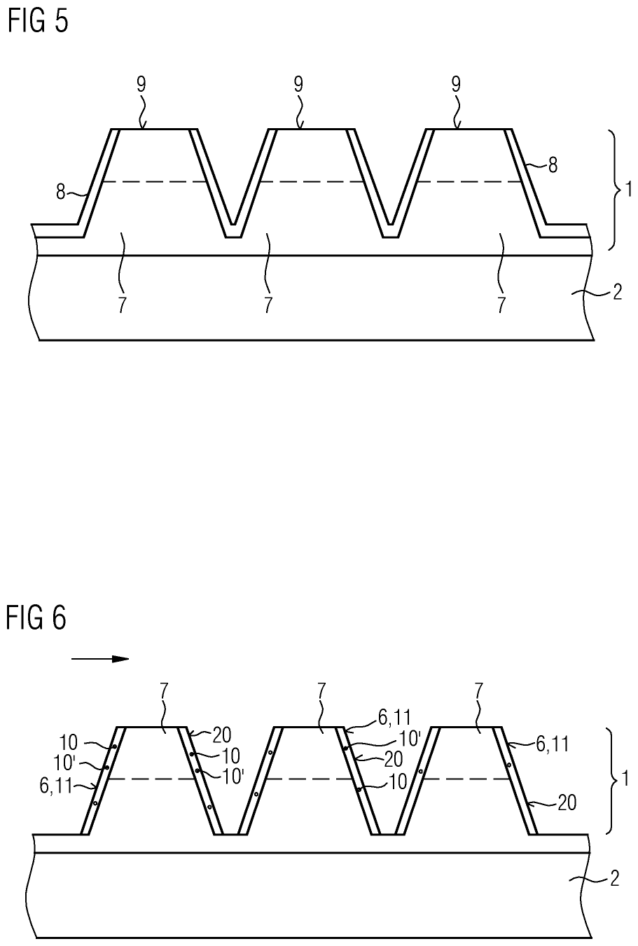

In a next step, the structured photoresist layer 4 is removed again (FIG. 5). Here, the aluminum-containing layer 8 is removed from the main surfaces 9 of the epitaxial semiconductor layer stacks 7.

In a next step, the epitaxial semiconductor layer sequence 1 is annealed so that aluminum atoms 10 and/or aluminum ions 10′ are introduced from the aluminum-containing layer 8 at the side surfaces 6 along the main surface 5 (see arrow) into the epitaxial semiconductor layer sequence 1 and in particular into the active zone 3, for example by diffusion (FIG. 6).

Alternatively, it is also possible to operate the active zones 3 of the epitaxial semiconductor layer stacks 7 so that electromagnetic radiation generated in the active zone is emitted from side surfaces 11 of the epitaxial semiconductor layer stacks 7, thus heating the side surfaces 11. Also in this way, aluminum atoms 10 and/or aluminum ions 10′ can be introduced into the epitaxial semiconductor layer stack 1 at the side surfaces 11.

If there is still material of the aluminum-containing layer 8 on the side surfaces 6 of the epitaxial semiconductor layer sequence 1, these can be removed, for example with wet chemical cleaning.

Alternatively, it is also possible to oxidize or nitride remaining material of the aluminum-containing layer 8 on the side surfaces 6 of the epitaxial semiconductor layer sequence 1 so that AlOₓ and/or AlN is formed. By removing remaining material of the aluminum-containing layer 8 or by forming an oxide or a nitride from the remaining material of the aluminum-containing layer 8 on the side surfaces 6 of the epitaxial semiconductor layer sequence 1, in particular a short circuit via residues of the aluminum-containing layer 8 on the side surfaces 20 of the finished optoelectronic semiconductor chip is prevented.

Finally, the epitaxial semiconductor layer stacks 7 are singulated along the etched trenches to form a plurality of optoelectronic semiconductor chips (not shown). The side surface 11 of the epitaxial semiconductor layer stack 7 at least partially forms a side surface 20 of the finished light-emitting diode chip.

In the method according to the exemplary embodiment of FIGS. 1 to 6, in particular a plurality of optoelectronic semiconductor chips is produced, which are embodied as light-emitting diode chips. An edge length of the generated light-emitting diode chips is, in particular, comparatively small.

For example, an edge length of the light-emitting diode chips is between 2 micrometers and 100 micrometers, inclusive or between 5 micrometers and 20 micrometers, inclusive.

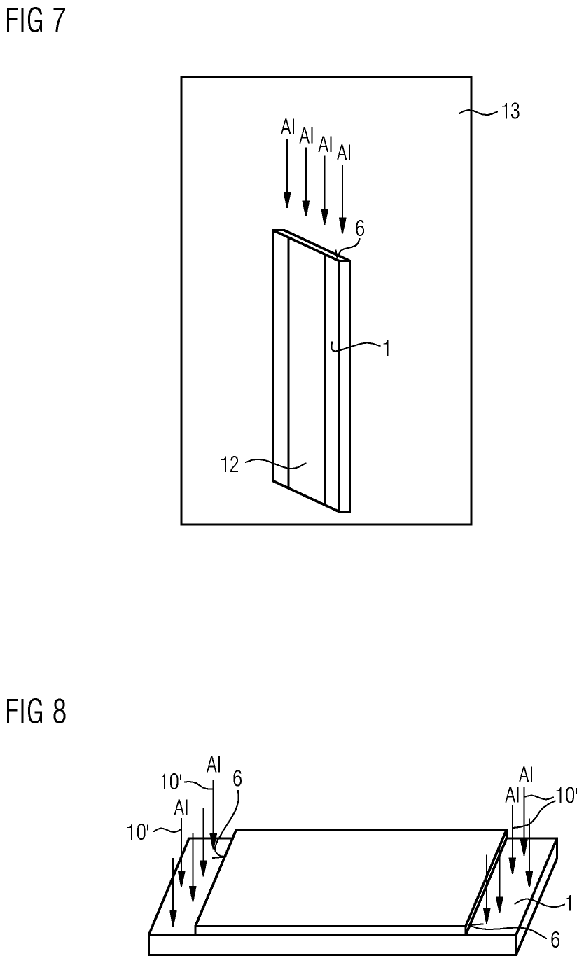

In the method according to the exemplary embodiment of FIG. 7, an edge-emitting laser diode chip is generated.

For this purpose, an epitaxial semiconductor layer sequence 1 is first provided and at least one side surface 6 is generated in the epitaxial semiconductor layer sequence 1 (not shown). Furthermore, a metal contact 12 is applied to the epitaxial semiconductor layer sequence 1. In particular, the side surface 6 is provided as a facet of the finished edge-emitting laser diode chip.

The epitaxial semiconductor layer sequence 1 and, in particular, the side surface 6 in the epitaxial semiconductor layer sequence 1 are first cleaned and, directly following the cleaning, coated with an aluminum-containing layer 8. By way of example, the cleaning and the deposition of the aluminum-containing layer 8 take place in an evacuated reaction volume 13, preferably in the same reaction volume 13. Between the cleaning and the deposition of the aluminum-containing layer 8, the epitaxial semiconductor layer sequence 1 is not removed from the reaction volume 13.

After depositing the aluminum-containing layer 8, for example by MBE or sputtering, an annealing step or a burn-in step is performed to introduce aluminum atoms 10 and/or aluminum ions 10′ from the aluminum-containing layer 8 into the epitaxial semiconductor layer sequence 1 so that an aluminum content at the side surface 6 of the epitaxial semiconductor layer sequence 1 is increased. Directly thereafter, a mirror layer 14 is then deposited on the side surface 6 (not shown) to form a resonator of the edge-emitting laser diode chip.

In the method according to the exemplary embodiment shown in FIG. 8, an epitaxial semiconductor layer sequence 1 is first provided. Then, side surfaces 6 are generated in the epitaxial semiconductor layer sequence 1 by means of a focused ion beam.

In this case, the epitaxial semiconductor layer sequence 1 is provided as part of a wafer and a plurality of side surfaces 6 are formed in the epitaxial semiconductor layer sequence 1 by means of the focused ion beam. In other words, the method according to the exemplary embodiment of FIG. 8 takes place at wafer level.

In the present case, the focused ion beam contains aluminum ions 10′ or is formed from aluminum ions 10′. By using a focused ion beam with aluminum ions 10′ for etching the side surfaces 6 in the epitaxial semiconductor layer sequence 1, aluminum atoms 10 and/or aluminum ions 10′ at the side surface 6 are introduced into the epitaxial semiconductor layer sequence 1 and, in particular, into the active zone 3 as they are formed.

Furthermore, it is also possible to create the side surfaces 6 by a focused ion beam comprising or consisting of gallium ions and/or helium ions and thereafter introduce aluminum atoms 10 and/or aluminum ions 10′ into the side surfaces 6 in the epitaxial semiconductor layer sequence 1.

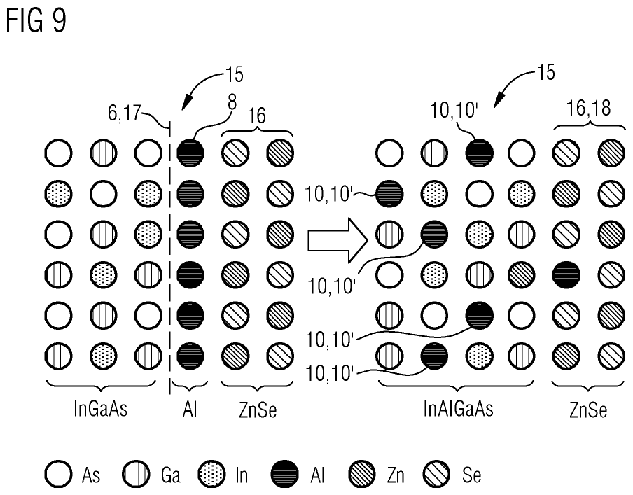

In a next step, the epitaxial semiconductor layer sequence 1 is annealed or a burn-in step is carried out so that the aluminum atoms 10 and/or the aluminum ions 10′ migrate to the designated lattice sites in a crystal structure 15 of the epitaxial semiconductor layer sequence 1 (compare also FIG. 9). Due to the aluminum atoms 10 and/or the aluminum ions 10′ in the region of the side surfaces 6 of the epitaxial semiconductor layer sequence 1, a band gap of the active zone 3 is increased here.

FIG. 9 schematically shows in the left part a crystal structure 15 of an epitaxial semiconductor layer sequence 1, which is based on or consists of InGaAs. On a side surface 6 of the epitaxial semiconductor layer sequence 1 a monolayer of aluminum is deposited as aluminum-containing layer 8. Subsequent to the aluminum-containing layer 8, a dielectric encapsulation layer 16 is further deposited, which comprises ZnSe or consists of ZnSe.

The epitaxial semiconductor layer sequence 1 with the aluminum-containing layer 8 and the dielectric encapsulation layer 16 is now annealed or a burn-in step is performed. Thus, aluminum atoms 10 and/or aluminum ions 10′ migrate from the aluminum-containing layer 8 into the epitaxial semiconductor layer sequence 1 and occupy corresponding lattice sites there (right part of FIG. 9).

For example, FIG. 9 shows a facet 17 of an edge-emitting laser diode chip at the level of a quantum film of an active zone 3. The dielectric encapsulation layer 16 may also be a mirror layer 18.

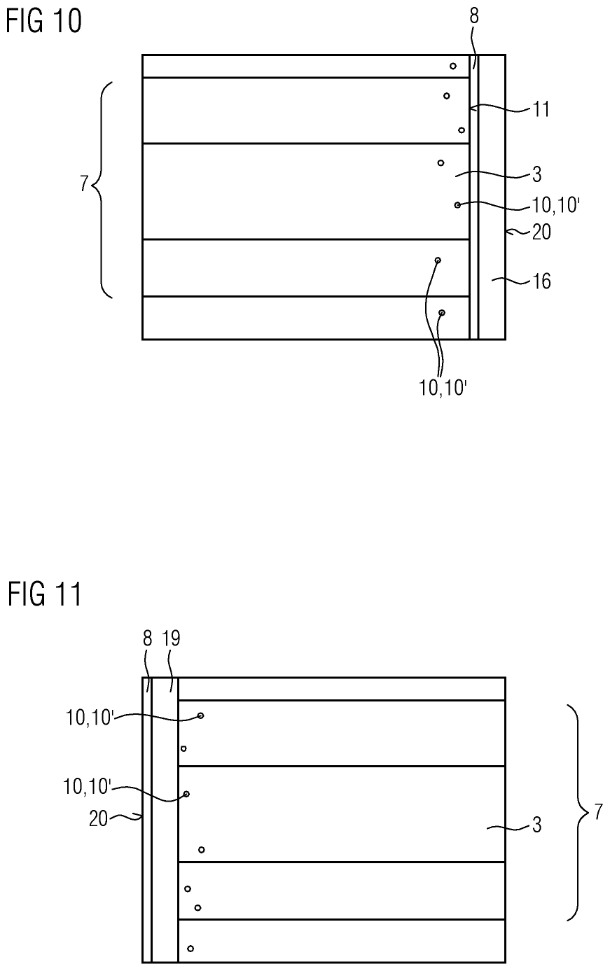

The optoelectronic semiconductor chip according to the exemplary embodiment of FIG. 10 is an edge-emitting laser diode chip. The edge-emitting laser diode chip according to the exemplary embodiment of FIG. 10 has an epitaxial semiconductor layer stack 7 with an active zone 3 in which electromagnetic radiation is generated during operation. An aluminum-containing layer 8 is provided on a side surface 11 of the epitaxial semiconductor layer stack 7. Finally, a dielectric encapsulation layer 16 is disposed on the aluminum-containing layer 8 in direct contact. By annealing, aluminum atoms 10 and/or aluminum ions 10′ are introduced from the aluminum-containing layer 8 into the active zone 3.

The edge-emitting laser diode chip according to the exemplary embodiment of FIG. 11 has, compared to the edge-emitting laser diode chip according to the exemplary embodiment of FIG. 10, a spacer layer 19 disposed between the side surface 11 of the epitaxial semiconductor layer stack 7 and the aluminum-containing layer 8.

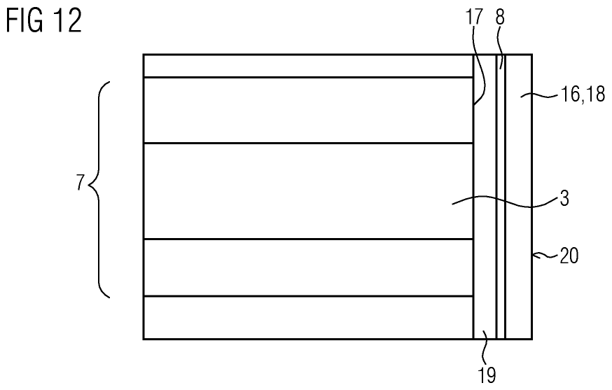

The edge-emitting laser diode chip according to the exemplary embodiment of FIG. 12 also has a spacer layer 19 which is applied directly to the side surface 11 of the epitaxial semiconductor layer stack 7. An aluminum-containing layer 8 is further disposed on the spacer layer 19. For example, the spacer layer 19 can comprise AlOₓ or can consist of AlOₓ. Finally, a dielectric encapsulation layer 16 is applied to the aluminum-containing layer 8. The dielectric encapsulation layer 16 can also be formed as a mirror layer 18.

The invention is not limited to these by the description based on the embodiments. Rather, the invention encompasses any new feature as well as any combination of features, which in particular includes any combination of features in the patent claims, even if this feature or combination itself is not explicitly stated in the patent claims or embodiments.

1. A method of manufacturing an optoelectronic semiconductor chip comprising:
providing an epitaxial semiconductor layer sequence having an active zone configured to generate electromagnetic radiation in operation,
structuring the epitaxial semiconductor layer sequence so that at least one side surface is formed in the epitaxial semiconductor layer sequence,
introducing aluminum atoms and/or aluminum ions at the side surface into the epitaxial semiconductor layer sequence so that a band gap of the active zone at the side surface is increased,
wherein introducing the aluminum atoms and/or the aluminum ions at the side surface into the epitaxial semiconductor layer sequence comprises:
depositing an aluminum-containing layer on the side surface of the epitaxial semiconductor layer sequence, and
annealing the side surface with the aluminum-containing layer.

2. (canceled)

3. The method according to claim 1, wherein the aluminum-containing layer is deposited on the side surface of the epitaxial semiconductor layer sequence by one of the following methods: evaporation, sputtering, PVD, ALD, MBE, MOVPE.

4. The method according to claim 1, wherein the thickness of the aluminum-containing layer is between 1 nanometer and nanometers, inclusive.

5. The method according to claim 1, wherein the aluminum atoms and/or the aluminum ions are introduced into the epitaxial semiconductor layer sequence with ion implantation or with a focused ion beam.

6. The method according to claim 1, wherein
the side surface in the epitaxial semiconductor layer sequence is formed with a focused ion beam comprising aluminum ions, and
the aluminum atoms and/or the aluminum ions are introduced into the epitaxial semiconductor layer sequence simultaneously with the formation of the side surface.

7. The method according to claim 1, wherein a dielectric encapsulation layer is applied to the aluminum-containing layer.

8. The method according to claim 7, wherein the dielectric encapsulation layer comprises one of the following materials: SiN, SiO₂, TaO, TiO₂, AlN, AlOₓ, HfO.

9. The method according to claim 1, wherein a material of the aluminum-containing layer remaining on the side surface is removed from the side surface after the aluminum atoms and/or the aluminum ions have been introduced into the epitaxial semiconductor layer sequence.

10. The method according to claim 1, wherein a material of the aluminum-containing layer remaining on the side surface is converted into a dielectric after the aluminum atoms and/or the aluminum ions are introduced into the epitaxial semiconductor layer sequence.

11. The method according to claim 1, wherein a spacer layer is arranged between the aluminum-containing layer and the side surface.

12. The method according to claim 1, wherein a mirror layer is applied over the aluminum-containing layer.

13. The method according to claim 1, wherein
the semiconductor chip is an edge-emitting laser diode chip, and
the side surface is a facet of the edge-emitting laser diode chip.

14. The method according to claim 1, wherein
introducing the aluminum atoms and/or the aluminum ions into the epitaxial semiconductor layer sequence comprises:
applying an aluminum-containing layer, and
operating the edge-emitting laser diode chip so that aluminum atoms and/or aluminum ions from the aluminum-containing layer diffuse into the epitaxial semiconductor layer sequence.

15. The method according to claim 14, wherein
a mirror layer is deposited over the aluminum-containing layer, and
a spacer layer is arranged between the aluminum-containing layer and the mirror layer.

16. The method according to claim 1, wherein
the optoelectronic semiconductor chip is a light-emitting diode chip, and
the side surface of the epitaxial semiconductor layer sequence forms a side surface of the light-emitting diode chip.

17. An optoelectronic semiconductor chip comprising:
an epitaxial semiconductor layer stack having an active zone configured to generate electromagnetic radiation in operation,
a side surface,
wherein
an aluminum content of the epitaxial semiconductor layer stack is increased at the side surface so that a band gap of the active zone is increased at the side surface of the epitaxial semiconductor layer stack, and
a spacer layer is arranged between the aluminum-containing layer and the side surface.

18. The optoelectronic semiconductor chip according claim 17, wherein the aluminum content decreases continuously starting from the side surface of the epitaxial semiconductor layer stack.

19. A method of manufacturing an optoelectronic semiconductor chip comprising:
providing an epitaxial semiconductor layer sequence having an active zone configured to generate electromagnetic radiation in operation;
structuring the epitaxial semiconductor layer sequence so that at least one side surface is formed in the epitaxial semiconductor layer sequence; and
introducing aluminum atoms and/or aluminum ions at the side surface into the epitaxial semiconductor layer sequence so that a band gap of the active zone at the side surface is increased, wherein
introducing the aluminum atoms and/or the aluminum ions into the epitaxial semiconductor layer sequence comprises,
applying an aluminum-containing layer, and
operating the edge-emitting laser diode chip so that aluminum atoms and/or aluminum ions from the aluminum-containing layer diffuse into the epitaxial semiconductor layer sequence.
